(19) United States
(12) Patent Application Publication
(10) Pub. No.: US 2007/0215318 A1
(43) Pub. Date: Sep. 20, 2007

(54) Heat dissipating device

(76) Inventor: Li-Wei Fan Chiang, Taoyuan Hsien (TW)

Correspondence Address: Li-Wei Fan Chiang, 235 Chung-Ho, Box 8-24 Taipei, Taoyuan Hsien, TW

(21) Appl. No.: 11/374,607

(22) Filed: Mar. 14, 2006

(51) Int. Cl. H05K 7/20

(52) U.S. Cl. 165/78; 165/185; 361/704

(57) ABSTRACT

A heat dissipating device comprises a plurality of fins. Each of an upper side and a lower side of the fin is folded as a vertical folding sheet. An unfolded portion of the fin is cut to form four cutting hole. Each hole is formed with a buckling sheet. An upper side of the buckling sheet is a flat surface. Each of two sides of the flat surface is extended with a convex surface. An incline surface is connected to the convex surface. A lateral surface is connected to the inclined surface. A lower side of the buckling sheet is formed with a slot. The shape of the slot is corresponding to that of an upper portion of the buckling sheet. In another design, the buckling sheets are extended from the folded sheets and the holes are formed on the folded sheets and below the buckled sheets.

### FIELD OF THE INVENTION

The present invention relates to heat dissipating devices, and in particular to a heat dissipating device, wherein each fin has buckling sheets and holes corresponding to the buckling sheets. Each hole is installed with a buckle so that the fins of the heat dissipating device can be firmly secured. The installation work can be performed easily and quickly. Thereby the present invention provides a preferred heat dissipating effect.

### BACKGROUND OF THE INVENTION

In the prior art heat dissipating device, a plurality of fins 100 are formed. Each fin 100 has a U shape and has an upper folded edge 200 and a lower folded edge 300 (referring to FIG. 7). Each folding edge 200, 300 has an ear 400. A hole 500 is formed at a rear side of the ear 400. The size of the hole 500 is slightly greater than that of the ear 400. In assembly, the ear 400 of one fin 100 is embedded into the hole 500 of another fin 100 so as to combine two fins 100. The heat dissipating device can be installed to a computer central processing unit. However the prior art ear has a simple structure. Thereby the buckling structure is easily released. Furthermore, the thermal expansion and cold contract increases the problem. This induces a trouble to users and increases the cost. It is necessary to be improved.

### SUMMARY OF THE INVENTION

Accordingly, the primary object of the present invention is to provide a heat dissipating device, wherein each fin has buckling sheets and holes corresponding to the buckling sheets. Each hole is installed with a buckle so that the fins of the heat dissipating device can be firmly secured. The installation work can be performed easily and quickly. Thereby the present invention provides a preferred heat dissipating effect.

To achieve above objects, the present invention provides a heat dissipating device. The heat dissipating device comprises a plurality of fins. Each fin is made of elastic and bendable material. Each of an upper side and a lower side of the fin is folded as a vertical folding sheet. An unfolded portion of the fin is cut to form four cutting hole near four corners of the unfolded portion. Each hole is formed with a buckling sheet. An upper side of the buckling sheet is a flat surface. Each of two sides of the flat surface is extended with a convex surface. An incline surface is connected to the convex surface. A lateral surface is connected to the inclined surface; the lateral surface is vertical to the flat surface; a lower side of the buckling sheet is formed with a slot. The shape of the slot is corresponding to that of an upper portion of the buckling sheet so that another buckling sheet can be embedded into the slot. One side of the hole is extended with a buckle; the hole has the effect of ventilation and heat dissipation. In assembly, the buckling sheets of one fin is assembled to the holes of another fin; the plurality of fins are assembled as a heat dissipating device; the heat dissipating set can be installed to a computer central processing unit.

Moreover in another design of the present invention, the buckling sheets are extended from the folded sheet and the holes are formed on the folded sheets and below the buckled sheets.

The various objects and advantages of the present invention will be more readily understood from the following detailed description when read in conjunction with the appended drawing.

### BRIEF DESCRIPTION OF THE DRAWINGS

FIG. 1 is a front perspective view about one fin of the present invention.

FIG. 2 is a back perspective view about one fin of the present invention.

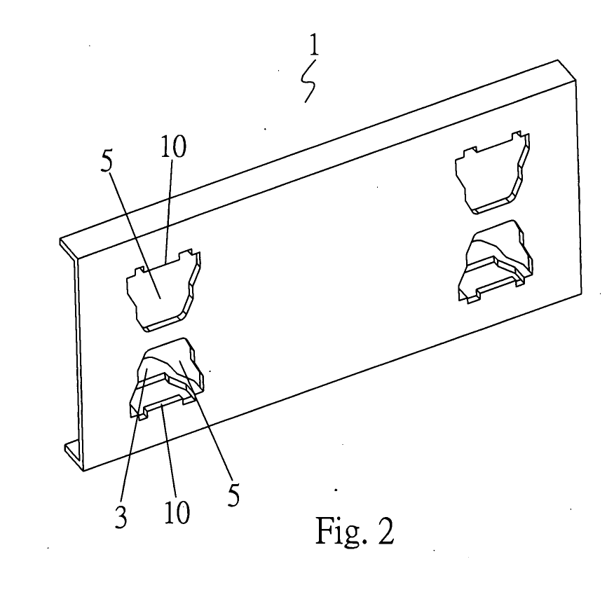

FIG. 3 shows the assembly of two fins according to the present invention.

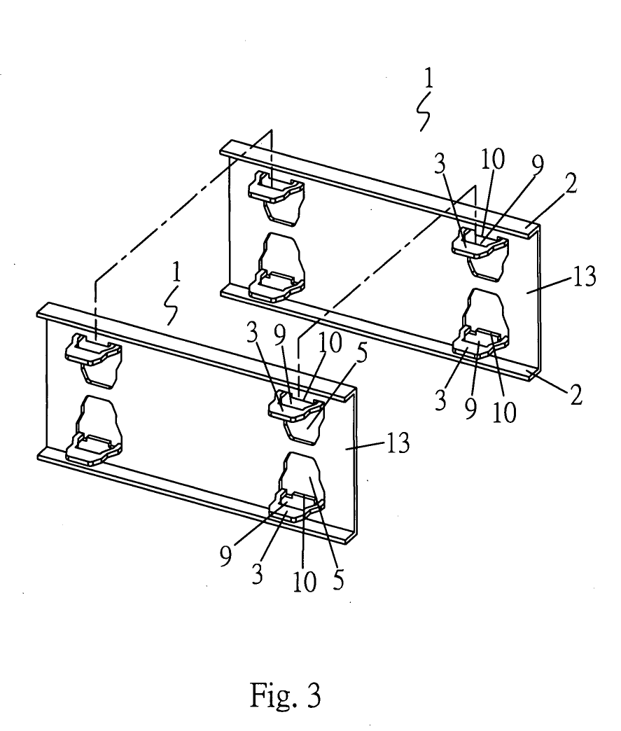

FIG. 4 shows the assembled view about two fins of the heat dissipating device of the present invention.

FIG. 5 shows an assembled heat dissipating device of the present invention.

FIG. 6 shows the second embodiment of the heat dissipating device suitable for a computer central processing unit of the present invention.

FIG. 7 shows the prior art heat dissipating device.

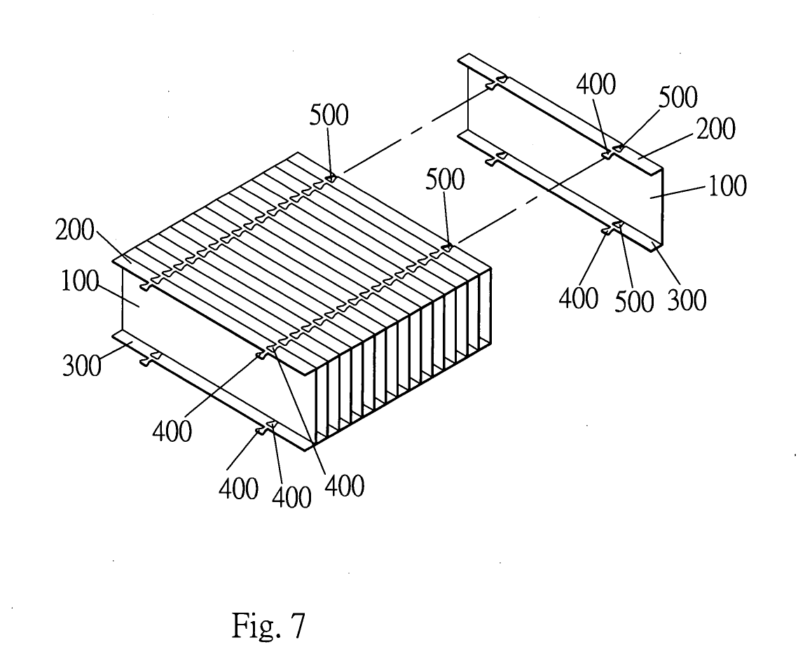

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

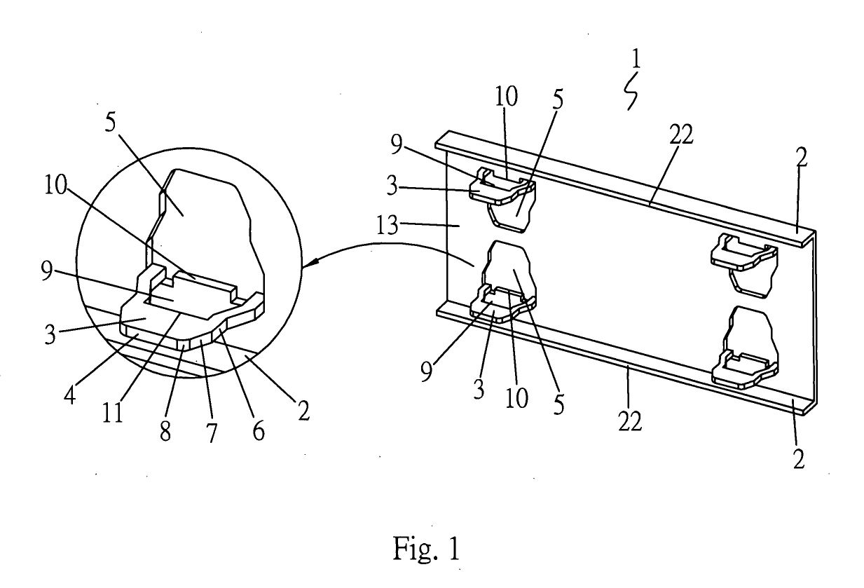

Referring to FIGS. 1 2, and 3, the heat dissipating fin of the present invention is the present invention. The heat dissipating fin has the following elements.

A fin 1 is made of elastic and bendable material, such as an aluminum sheet or a copper sheet. Each of an upper side and a lower side of the fin 1 is folded as a vertical folding sheet 2. The unfolded portion 13 of the fin 1 is cut to form four cutting hole 5 near four corners of the unfolded portion 13. Each hole 5 is formed with a buckling sheet 3. An upper side of the buckling sheet 3 is a flat surface 4. Each of two sides of the flat surface 4 is extended with a convex surface 8. An incline surface 7 is connected to the convex surface 8. A lateral surface 6 is connected to the inclined surface 7. The lateral surface 6 is vertical to the flat surface 4. A lower side of the buckling sheet 3 is formed with a slot 9. The shape of the slot 9 is corresponding to that of an upper portion of the buckling sheet 3 so that another buckling sheet 3 can be embedded into the slot 9. One side of the hole 5 is extended with a buckle 10. The hole 5 has the effect of ventilation and heat dissipation.

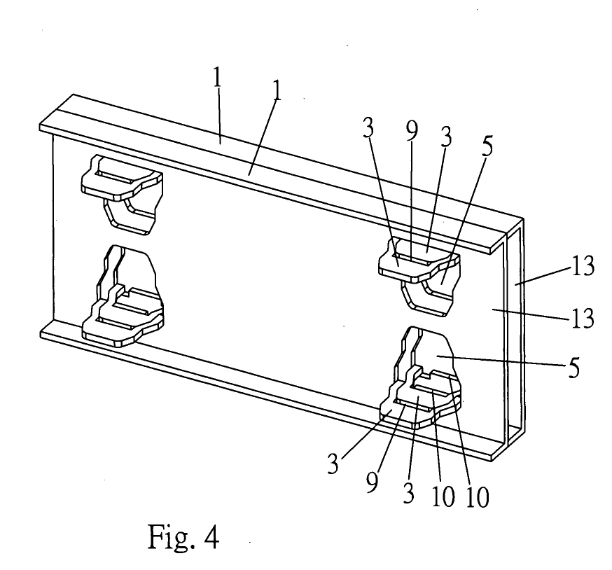

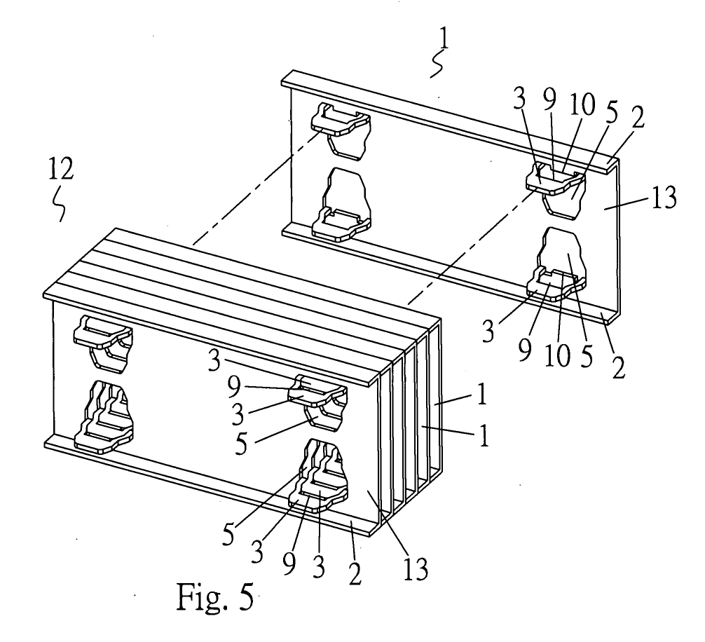

In assembly, the buckling sheets 3 of one fin 1 are assembled to the holes 5 of another fin 1, as shown in FIG. 4. A plurality of fins 1 are assembled as a heat dissipating set 12 (referring to FIG. 5). The assembly is firm and concrete. The heat dissipating set 12 can be installed to a computer central processing unit. The assembly work is easy and quick with a good heat dissipating effect.

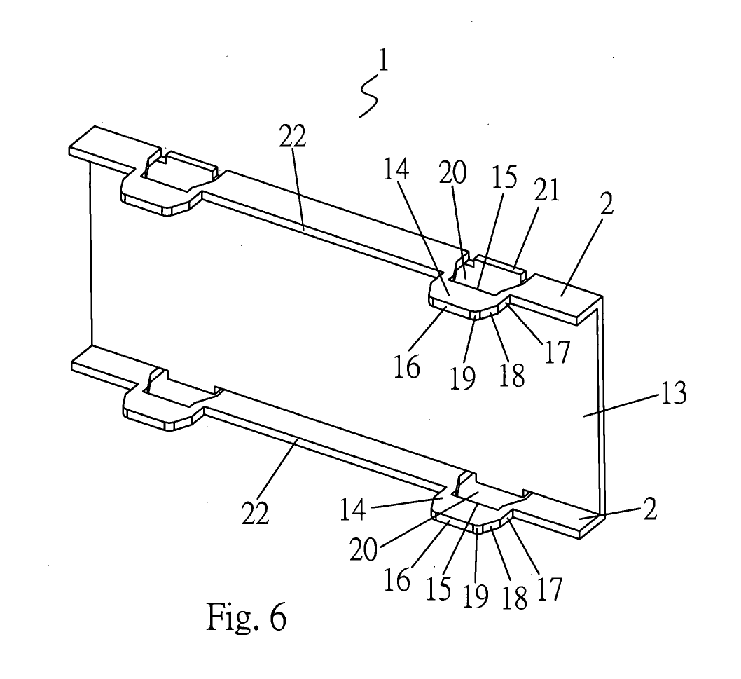

Referring to FIG. 6, the second embodiment of the present invention is illustrated. The heat dissipating fin has the following elements.

A fin 1 is made of elastic and bendable material, such as an aluminum sheet or a copper sheet. Each of an upper side and a lower side of the fin 1 is folded as a vertical folding sheet 2. Each of two sides of each fin 1 is cut to form a cutting hole 20. Each hole 20 is formed with a buckling sheet 14. A lower side of the buckling sheet 14 is formed with a resisting surface 15. An upper side of the buckling sheet 14 is a flat surface 16. Each of two sides of the flat surface 16 is extended with a convex surface 19. An incline surface 18 is connected to the convex surface 19. A lateral surface 17 is connected to the inclined surface 18. The lateral surface 17 is vertical to the flat surface 16. The shape of the hole 20 is corresponding to that of an upper portion of the buckling sheet 14 so that another buckling sheet 14 can be embedded into the hole 20. The hole 20 is located below the buckling sheet 14. The hole 20 has the effect of ventilation and heat dissipation. Each of the holes 20 is formed with a buckle 21 which is extended from a non-folded portion 13 of the fin 1.

In assembly, the buckling sheets 14 of one fin 1 are assembled to the holes 20 of another fin 1 with the buckle 21 resisting against a resisting surface 15 of the buckling sheet 14. A plurality of fins 1 are assembled as a heat dissipating set. The assembly is firm and concrete. The heat dissipating set can be installed to a computer central processing unit. The assembly work is easy and quick with a good heat dissipating effect.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A heat dissipating device comprising:
a plurality of fins, wherein
each fin is made of elastic and bendable material; each of an upper side and a lower side of the fin is folded as a vertical folding sheet; an unfolded portion of the fin is cut to form four cutting holes near four corners of the unfolded portion; each hole is formed with a buckling sheet; an upper side of the buckling sheet is a flat surface; each of two sides of the flat surface is extended with a convex surface; an incline surface is connected to the convex surface; a lateral surface is connected to the inclined surface; the lateral surface is vertical to the flat surface; a lower side of the buckling sheet is formed with a slot; the shape of the slot is corresponding to that of an upper portion of the buckling sheet so that another buckling sheet can be embedded into the slot; one side of each hole is extended with a buckle; the holes have the effect of ventilation and heat dissipation;
wherein in assembly, the buckling sheets of one fin are assembled to the holes of another fin; the plurality of fins are assembled as a heat dissipating device; the heat dissipating set can be installed to a computer central processing unit.

2. A heat dissipating device comprising:
a plurality of fins, wherein
each fin is made of elastic and bendable material; each of an upper side and a lower side of the fin is folded as a vertical folding sheet; each of two sides of each fin is cut to form a cutting hole; each hole is formed with a buckling sheet; a lower side of the buckling sheet is formed with a resisting surface; an upper side of the buckling sheet is a flat surface; each of two sides of the flat surface is extended with a convex surface; an incline surface is connected to the convex surface; a lateral surface is connected to the inclined surface; the lateral surface is vertical to the flat surface; the shape of the hole is corresponding to that of an upper portion of the buckling sheet so that another buckling sheet can be embedded into the hole; each hole is located below a respective one of the buckling sheets; the holes have the effect of ventilation and heat dissipation; each of the holes is formed with a buckle which is extended from a non-folded portion of the fin;
wherein in assembly, the buckling sheets of one fin are assembled to the holes of another fin with the buckle resisting against a resisting surface of the buckling sheet; the plurality of fins are assembled as a heat dissipating set; the heat dissipating set can be installed to a computer central processing unit.
